(19) United States
(12) Patent Application Publication
(10) Pub. No.: US 2007/0148346 A1
(43) Pub. Date: Jun. 28, 2007

(54) Systems and methods for deposition of graded materials on continuously fed objects

(75) Inventors: Tae Won Kim, Medina, OH (US); Anil Raj Duggal, Niskayuna, NY (US); Paul Alan McConnelee, Schenectady, NY (US); Michael Anthony Rumsey, Niskayuna, NY (US); Marc Schaepkens, Medina, OH (US); Reinhold Franz Wirth, Chandler, AZ (US); Min Yan, Schenectady, NY (US); Ahmet Gun Erlat, Clifton Park, NY (US); Thomas Paul Feist, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/315,248

(22) Filed: Dec. 23, 2005

(51) Int. Cl. C23C 16/00; H05H 1/24

(52) U.S. Cl. 427/248.1; 427/569; 118/718

(57) ABSTRACT

Embodiments of the invention include a deposition machine that allows for continuous deposition of an object or substrate with a coating having a graded composition. The deposition machine includes a deposition chamber separated into a plurality of chamber areas by a baffle having an opening. The opening allows for migration of deposition material from one chamber area to another, allowing for a graded composition coating to be deposited on the object or substrate. Other embodiments include a system for forming an electronic device and a system and method for forming a graded composition on an object.

### BACKGROUND

The invention generally relates to the deposition of graded materials, and more particularly, to the deposition of materials in such a way as to provide graded coatings having a varying composition on objects transported through a deposition chamber.

Electroluminescent (“EL”) devices, which may be classified as either organic or inorganic, are well known in the graphic display and imaging art. EL devices have been produced in different shapes for many applications. Inorganic EL devices, however, typically suffer from a required high activation voltage and low brightness. On the other hand, organic EL devices (“OELDs”), which have been developed more recently, offer the benefits of lower activation voltage and higher brightness in addition to simple manufacture, and, thus, the promise of more widespread applications.

An OELD is typically a thin film structure formed on a substrate such as glass, metal or plastic. A light-emitting layer of an organic EL material and optional adjacent semiconductor layers are sandwiched between a cathode and an anode. The semiconductor layers may be either hole (positive charge)-injecting or electron (negative charge)-injecting layers and also may comprise organic materials. The material for the light-emitting layer may be selected from many organic EL materials. The light emitting organic layer may itself consist of multiple sublayers, each comprising a different organic EL material. State-of-the-art organic EL materials can emit electromagnetic (“EM”) radiation having narrow ranges of wavelengths in the visible spectrum. Unless specifically stated, the terms “EM radiation” and “light” are used interchangeably in this disclosure to mean generally radiation having wavelengths in the range from ultraviolet (“UV”) to mid-infrared (“mid-IR”) or, in other words, wavelengths in the range from about 300 nm to about 10 micrometer. To achieve white light, prior-art devices incorporate closely arranged OELDs emitting blue, green, and red light. These colors are mixed to produce white light.

Conventional OELDs are built on glass substrates because of a combination of transparency and low permeability of glass to oxygen and water vapor. A high permeability of these and other reactive species can lead to corrosion or other degradation of the devices. However, glass substrates are not suitable for certain applications in which flexibility is desired. In addition, manufacturing processes involving large glass substrates are inherently slow and, therefore, result in high manufacturing cost. Flexible plastic substrates have been used to build OLEDs. However, these substrates are not impervious to oxygen and water vapor, and, thus, are not suitable per se for the manufacture of long-lasting OELDs. In order to improve the resistance of these substrates to oxygen and water vapor, alternating layers of polymeric and ceramic materials have been applied to a surface of a substrate. It has been suggested that in such multilayer barriers, a polymeric layer acts to mask defects in an adjacent ceramic layer, and therefore provides a tortuous pathway to reduce the diffusion rates of oxygen and/or water vapor through the channels made possible by the defects in the ceramic layer. However, an interface between a polymeric layer and a ceramic layer is generally weak due to the incompatibility of the adjacent materials, and the layers, thus, are prone to be delaminated.

Organic electronics may supplant conventional silicon-based technology if they can be manufactured for large area electronic devices at a much lower cost. Examples of low-cost electronic technologies include organic light-emitting devices (OLEDs), organic photovoltaic devices, thin-film transistors (TFTs) and TFT arrays using organic and solution-processible inorganic materials, and other more complicated circuits. Such electronic technologies are conventionally manufactured using predominantly batch-mode semiconductor fabrication processes. Such processes do not, however, fulfill the promise of low cost and large area potential. Thus, considerable research effort is being directed to fabricating organic electronic devices using printing processes on roll-to-roll compatible, mechanically flexible substrates. For example, Konarka Technologies Inc. has developed a photovoltaic cell manufacturing process that allows printing photo-reactive materials onto flexible plastic substrate in continuous roll-to-roll (R2R) fashion, similar to how newspaper is printed on large rolls of paper. Konarka's R2R manufacturing process enables production to scale easily and results in significantly reduced costs over previous generations of solar cells. See, for example, U.S. patent application publication 2003/0192584. SiPix Imaging Inc. has developed a R2R manufacturing process that produces large arrays of microscale containers on a flexible plastic substrate that may be used to fabricate ultra-low power, high contrast electrophoretic display devices (electronic paper). See, for example, U.S. Pat. No. 6,873,452.

OLEDs represent the most advanced of current organic electronic technologies as evidenced by the fact that OLED display products are now commercially available. However, these products are still manufactured using predominantly batch-mode conventional semiconductor fabrication processes and so have still not demonstrated the low cost and large area potential of organic electronics. A key impediment for this effort is the lack of availability of a mechanically flexible substrate that fulfills all the requirements for a functional OLED device.

To meet the stringent requirements put forth for the design of OLEDs and other organic electronic devices on plastic substrates, a robust coating design should be realized which avoids easy defect pathways for permeation. Multilayer barrier structures including multiple sputter-deposited aluminum oxide inorganic layers separated by polymer multilayer (PML) processed organic layers have demonstrated promising moisture permeation rates in the range of 10⁻⁶-10⁻⁵ g/m²/day. It is commonly understood that organic layers may decouple defects in the inorganic layers and prevent the propagation of the defects from one inorganic layer to the other inorganic layers. In other words, the multilayer stack stops defects from propagating in the vertical direction through the coating thickness. A modeling study suggests that this defect decoupling forces a tortuous path for moisture and oxygen diffusion, and thus reduces the permeation rate by several orders of magnitude. Another study suggests that the inorganic-organic multilayer stack leads to higher performance through a transient rather than steady-state phenomenon. Regardless of mechanism, the multilayer barrier stack approach appears to be capable of yielding the required level of performance for OLED applications.

One potential limitation of the multilayer stack approach is that this type of structure tends to suffer from poor adhesion and delamination especially during thermal cycles of the OLED fabrication processes, since the inorganic and organic layers have sharp interfaces with weak bonding structure due to the nature of the sputter deposition and PML processes.

Therefore, there is a continued need to have robust films that have reduced diffusion rates of environmentally reactive materials. It is also very desirable to provide such films to produce flexible OELDs that are robust against degradation due to environmental elements.

### SUMMARY

One embodiment of the invention described herein is directed to a continuous deposition machine that includes a deposition chamber including at least two subchambers separated by a baffle having an opening, and a transportation device extending through the deposition chamber.

One aspect of the deposition machine includes a deposition chamber including a first chamber area separated from a second chamber area by a baffle having an opening, an unwinding chamber including an unwinding spool and a winding chamber including a winding spool, a substrate wound on the unwinding spool and extending through the deposition chamber to the winding spool, and a first chemical vapor deposition assembly located in the first chamber area and a second chemical vapor deposition assembly located in the second chamber area.

Another embodiment of the invention is directed to a system for forming a graded coating on an object including a continuous deposition machine that has a deposition chamber including at least two subchambers separated by a baffle having an opening, and a transportation device adapted for transporting an object through the deposition chamber. The system also includes a pump for enacting a vacuum in the deposition chamber.

Another embodiment of the invention is directed to a system for forming an electronic device. The system includes a deposition machine, a transportation device, and a pump. The deposition machine includes a deposition chamber having a first chamber area separated from a second chamber area by a baffle having an opening, a first deposition assembly in the first chamber area and a second deposition assembly in the second chamber area, and a first outlet configured to allow excess material to exit from the first chamber area and a second outlet configured to allow excess material to exit from the second chamber area. The first and second deposition assemblies are adapted for depositing materials on a substrate to form a coating on the substrate. The transportation device is adapted for continuously transporting the substrate through the deposition chamber. The pump is for enacting a vacuum in the deposition chamber.

Another embodiment of the invention is a method for forming a graded coating having a varying composition on an object. The method includes transporting an object through a deposition chamber including a first chamber area separated by a second chamber area by a baffle having an opening. The method also includes depositing a first substance and a second substance on a surface of the object to create a graded coating having a varying composition in a direction orthogonal to the surface of the object.

These and other advantages and features will be more readily understood from the following detailed description of preferred embodiments of the invention that is provided in connection with the accompanying drawings.

### BRIEF DESCRIPTION OF THE DRAWINGS

FIG. 1 is a schematic view of a deposition machine constructed in accordance with an exemplary embodiment of the invention.

FIG. 2 is a schematic view of the deposition chamber of the deposition machine of FIG. 1.

FIG. 3 is a schematic view illustrating graded deposition within the deposition chamber of the deposition machine of FIG. 1.

FIG. 4 is a schematic view of a deposition machine constructed in accordance with an exemplary embodiment of the invention.

FIG. 5 is a schematic side view of an object having been subjected to graded deposition in accordance with an exemplary embodiment of the invention.

FIGS. 6-9 illustrate various baffle and opening profiles of a deposition machine constructed in accordance with an exemplary embodiment of the invention.

FIG. 10 illustrates an arrangement of deposition assemblies of a deposition machine constructed in accordance with an exemplary embodiment of the invention.

FIG. 11 illustrates method steps for providing a graded deposition onto an object in accordance with an exemplary embodiment of the invention.

FIG. 12 illustrates optical emission spectrometry delineating organic process plasma spectra alone from the spectra of organic process plasma emission running adjacent to inorganic process plasma in the deposition machine of FIG. 1.

FIG. 13 illustrates optical emission spectrometry delineating inorganic process plasma spectra alone from the spectra of inorganic process plasma emission running adjacent to organic process plasma in the deposition machine of FIG. 1.

FIG. 14 illustrates optical emission spectrometry of organic process plasma spectra for variously sized openings in the deposition machine of FIG. 1.

FIG. 15 illustrates optical emission spectrometry of inorganic process plasma spectra for variously sized openings in the deposition machine of FIG. 1.

FIG. 16 illustrates optical emission spectrometry of inorganic process plasma spectra taken from various positions within the deposition machine of FIG. 1.

FIG. 17 illustrates a deposition rate of an organic coating process alone and an organic coating process running adjacent to an inorganic coating process in the deposition machine of FIG. 1.

FIG. 18 illustrates a refractive index of an organic coating process alone and an organic coating process running adjacent to an inorganic coating process in the deposition machine of FIG. 1.

FIG. 19 illustrates a deposition rate of an inorganic coating process alone and an inorganic coating process running adjacent to an organic coating process in the deposition machine of FIG. 1.

FIG. 20 illustrates a refractive index of an inorganic coating process alone and an inorganic coating process running adjacent to an organic coating process in the deposition machine of FIG. 1.

### DETAILED DESCRIPTION OF PREFERRED EMBODIMENTS

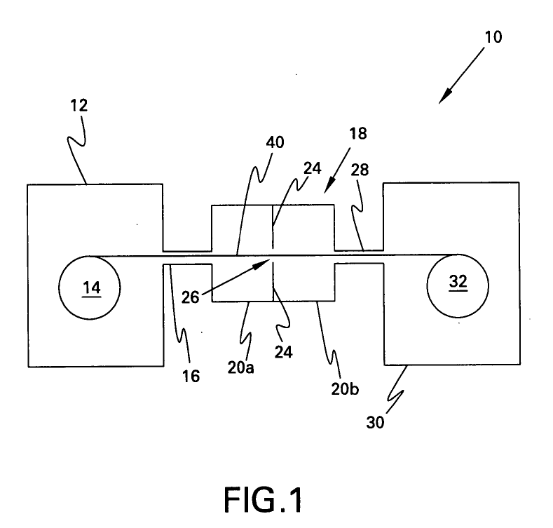

With specific reference to FIGS. 1-3, a deposition machine 10 is illustrated including a first spool chamber 12, a deposition chamber 18, and a second spool chamber 30. The deposition machine 10 may be configured to produce a graded-composition coating, for example a graded-composition diffusion-barrier coating, on an object. The first spool chamber 12 includes a first spool 14 about which a web 40 is wound. The web 40 extends through the deposition chamber 18 and into the second spool chamber to a second spool 32. In one exemplary embodiment, the first spool 14 is an unwinding spool and the second spool 32 is a winding spool. The web 40 may be a transportation device serving to transport an object through the deposition chamber 18. Examples of objects upon which deposition may occur include plastic film, plastic sheet, optoelectronic devices that have been built on glass, metal or plastic substrates, and any objects that need graded composition diffusion-barrier overcoat.

Alternately, the web 40 itself may be a substrate upon which a coating is to be deposited. Substrate materials that may benefit from having a graded-composition diffusion-barrier coating are organic polymeric materials, such as: polyethylene-terephthalate (“PET”); polyacrylates; polycarbonate; silicone; epoxy resins; silicone-functionalized epoxy resins; polyester, such as Mylar® (made by E.I. du Pont de Nemours & Co.); polyimide, such as Kapton® H or Kapton® E (made by du Pont), Apical® AV (made by Kanegafugi Chemical Industry Company), Upilex® (made by UBE Industries, Ltd.); polyethersulfones (“PES,” made by Sumitomo); polyetherimide such as Ultem® (made by General Electric Company); and polyethylenenaphthalene (“PEN”).

Suitable coating compositions of regions across the thickness are organic, inorganic, or combinations thereof of inorganic and organic. These materials are typically reaction or recombination products of reacting plasma species and are deposited onto the substrate surface. Organic coating materials typically comprise carbon, hydrogen, oxygen, and optionally other minor elements, such as sulfur, nitrogen, silicon, etc., depending on the types of reactants. Suitable reactants that result in organic compositions in the coating are straight or branched alkanes, alkenes, alkynes, alcohols, aldehydes, ethers, alkylene oxides, aromatics, etc., having up to 15 carbon atoms. Inorganic and ceramic coating materials typically comprise oxide; nitride; carbide; boride; or combinations thereof of elements of Groups IIA, IIIA, IVA, VA, VIA, VIIA, IB, and IIB; metals of Groups IIIB, IVB, and VB; and rare-earth metals. For example, silicon carbide can be deposited onto a substrate by recombination of plasmas generated from silane (SiH₄) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum tartrate and ammonia. Other combinations of reactants may be chosen to obtain a desired coating composition. The choice of the particular reactants is within the skills of the artisans. A graded composition of the coating is obtained by changing the compositions of the reactants fed into the reactor chamber during the deposition of reaction products to form the coating.

Coating thickness is typically in the range from about 10 nm to about 10000 nm, preferably from about 10 nm to about 1000 nm, and more preferably from about 10 nm to about 200 nm. It may be desired to choose a coating thickness that does not impede the transmission of light through the substrate, such as a reduction in light transmission being less than about 20 percent, preferably less than about 10 percent, and more preferably less than about 5 percent. The coating may be formed by one of many deposition techniques, such as plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), sputtering including reactive sputtering, electron-cyclotron-resonance plasma-enhanced chemical-vapor deposition (“ECRPECVD”), inductively coupled plasma-enhanced chemical-vapor deposition (“ICPECVD”), or combinations thereof. Alternately, the coating may be formed through an evaporative process.

Further discussion of suitable substrate materials, suitable coating compositions and suitable coating thicknesses is found in co-pending U.S. patent application Ser. No. 10/065018, filed Sep. 11, 2002 and currently owned by the assignee of the present patent application, the entirety of which is incorporated herein by reference.

An outlet 16 extends from the first chamber 12 to the deposition chamber 18 (FIG. 1). An outlet 28 extends from the deposition chamber 18 to the second chamber 32. The deposition chamber 18 includes at least a first chamber area or subchamber 20a and a second chamber area or subchamber 20b. The two chamber areas 20a, 20b are separated by a baffle 24. The baffle 24 has an opening 26. The opening 26 may be adjustable to control the rate of migration of deposition material through the opening 26. The deposition chamber 18 may be under vacuum. Further, for mechanical efficiency, the first and second chambers 12, 30 also may be under vacuum.

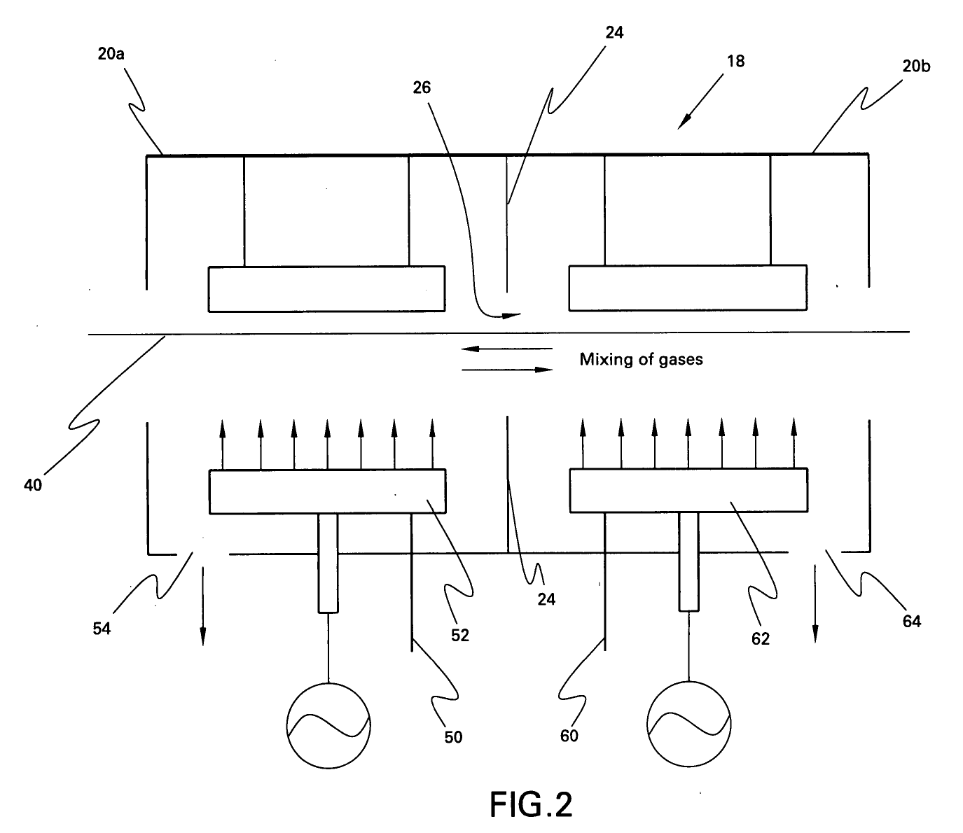

Each chamber area includes a deposition assembly, a deposition material outlet and a gas inlet. Specifically, and with reference to FIG. 2, the first chamber area 20a includes a gas inlet 50 extending to a deposition assembly 52. The gas inlet 50 receives a gaseous material which is transported to the deposition assembly 52 to create a deposition mist for the web 40 or any object being transported thereby. Any excess deposition material may be removed from the first chamber area 20a through the deposition material outlet 54. The second chamber area 20b includes a gas inlet 60 extending to a deposition assembly 62. The gas inlet 60 receives a gaseous material which is transported to the deposition assembly 62 to create a deposition mist for the web 40 or any object being transported thereby. Any excess deposition material may be removed from the second chamber area 20b through the deposition material outlet 64. The outlets 54, 64 each may be a single port in the respective deposition chamber area 20a, 20b. Alternatively, the outlets 54, 64 each may be multiple ports in the respective deposition chamber areas 20a, 20b. The location of each outlet 54, 64 within the deposition chamber areas 20a, 20b may be engineered to achieve desired gas flow and reactive species distribution.

To form a graded-composition coating on the object or the web 40, it is envisioned that the material received by the first deposition assembly 52 has a different composition than the material received by the second deposition assembly 62. For example, one material may be an organic material, while a second material is an inorganic material or combinations of inorganic and organic.

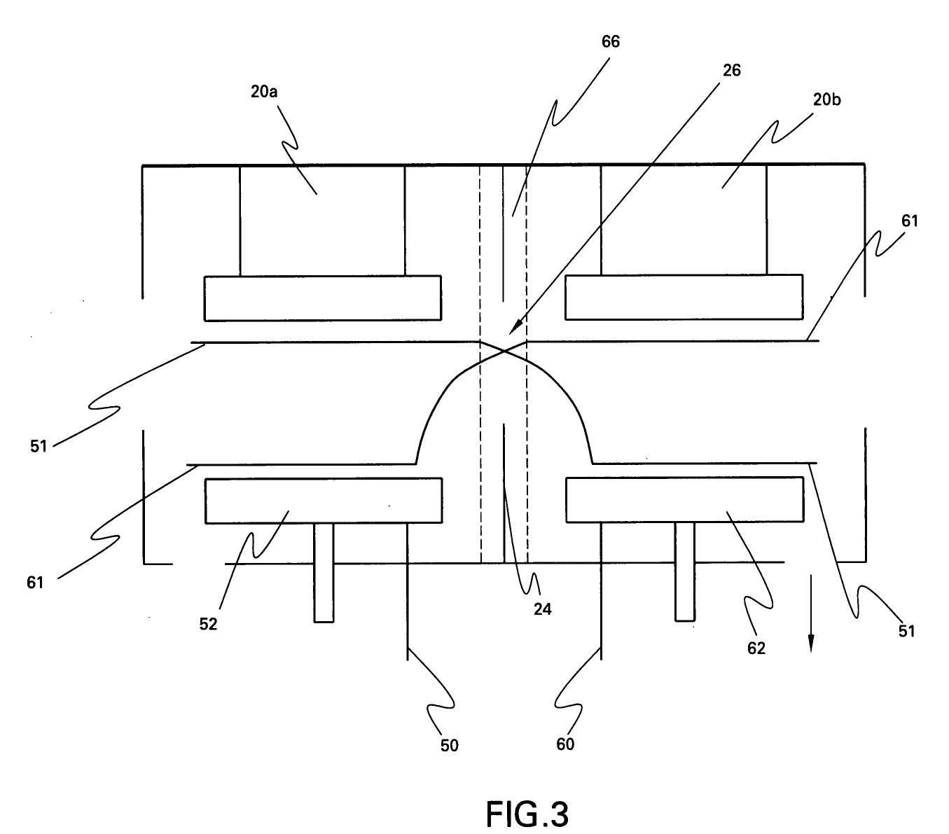

With specific reference to FIG. 3, a function of the baffle 24 and the opening 26 is further described. The baffle 24 is adjusted to create an opening 26 of sufficient size and configuration to allow a certain amount of migration of deposition material to occur from one chamber area to another chamber area. As schematically illustrated in FIG. 3, a gaseous material deposited by the first deposition assembly 52 results in a coating portion 51 having a relatively high composition of the first gaseous material. Also, a gaseous material deposited by the second deposition assembly 62 results in a coating portion 61 having a relatively high composition of the second gaseous material.

Excess deposition material is evacuated from each of the chamber areas 20a, 20b by pumping the material out through the respective outlets 54, 64. The pumping causes a localized pressure differential in each chamber area causing a migration of excess material from most of each the chamber areas 20a, 20b toward the outlets 54, 64. When the pressures in deposition chamber areas 20a and 20b are maintained at the same level, a mix area 66 is formed immediately adjacent to the baffle 24. There is no localized pressure differential in the mix area 66. In this mix area 66, deposition material from the second chamber area 20b is equally likely to migrate into the first chamber area 20a as remain in the second chamber area 20b and deposition material from the first chamber area 20a is equally likely to migrate into the second chamber area 20b as remain in the first chamber area 20a. In this mix area 66, the relative compositions of the deposition materials begin to change. For example, the composition of the coating portion 51 begins to drop in the mix area 66, while the composition of the coating portion 61 begins to increase as an object moves from the first chamber area 20a through the mix area 66 and into the second chamber area 20b. The pressures in deposition chamber areas 20a and 20b also may be deliberately set to different levels to shift the mix area 66 to various locations within the deposition chamber 18. For example, pressure in deposition chamber area 20a may be set lower than that of deposition chamber area 20b. Thus, deposition material from both deposition chamber area 20a and deposition chamber area 20b is more likely to migrate to outlet 54 and therefore mix area 66 will move into deposition chamber 20a. By engineering opening 26, pressures in deposition chamber areas 20a and 20b, gaseous mixture material flows to deposition assemblies 52 and 62, geometry and location of deposition assemblies 52 and 62, geometry and location of outlets 54 and 64, and other process parameters, desired material distribution profiles can be achieved in the deposition chamber areas 20a, 20b.

According to an exemplary embodiment, the web 40, either as a transportation device or as the substrate to be coated, is unwound from the first spool 14. As the web 40 travels through the deposition chamber 18, the first and second deposition assemblies 52, 62 begin depositing, respectively, the first and second materials. Through such a coating process, the web 40 (or object) is coated by a plurality of materials and in varying compositions along the thickness of the coating. For example, and with specific reference to FIG. 5, the web 40 (or object) may be coated such that the coating is graded into a first concentration zone 42, a second concentration zone 44, and a third concentration zone 46 in a direction orthogonal to a surface of the web 40 or object. The first concentration zone has a high concentration of the material being deposited from the first deposition assembly 52. The second concentration zone 44 has a decreasing concentration of the material being deposited from the first deposition assembly 52 and an increasing concentration of the material being deposited from the second deposition assembly 62. The third concentration zone 46 has a high concentration of the material being deposited from the second deposition assembly 62. Thus, the web 40 is provided with a coating that has a composition that varies in a direction A.

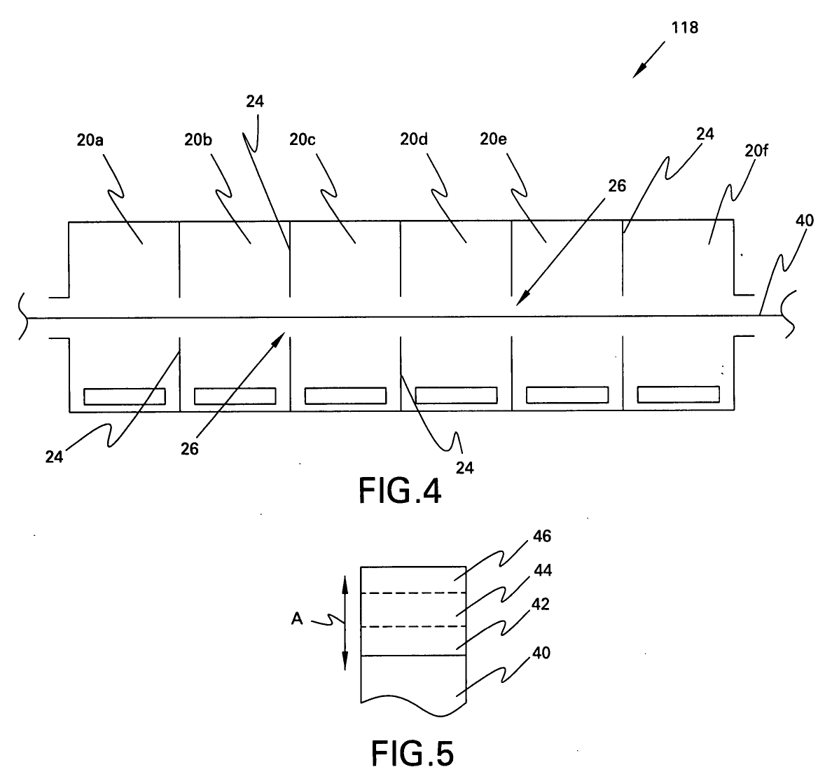

It should be appreciated that the web 40 can be wound through the deposition chamber 18 toward the second spool 32 and then wound back through the deposition chamber 18 toward the first spool 14 to obtain a coating having more than three graded zones. Alternatively, and with specific reference to FIG. 4, it should be appreciated that numerous chamber areas or subchambers may be positioned side by side through which the web 40 may be transported. As shown, the web 40 may be transported through a plurality of chamber areas 20a-20f, each being separated from the other by a baffle 24 having an adjustable opening 26. It should be further appreciated that such a deposition machine may be modularly assembled. For example, subchambers may be added to the deposition machine or removed from the deposition machine depending upon the particular application. By being to add and remove subchambers to the entire coating process, flexibility in applicability for the deposition machine is enhanced.

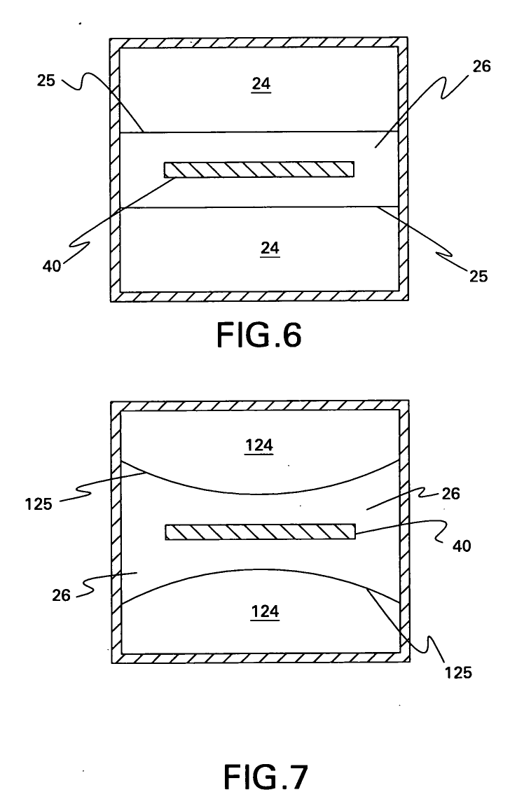

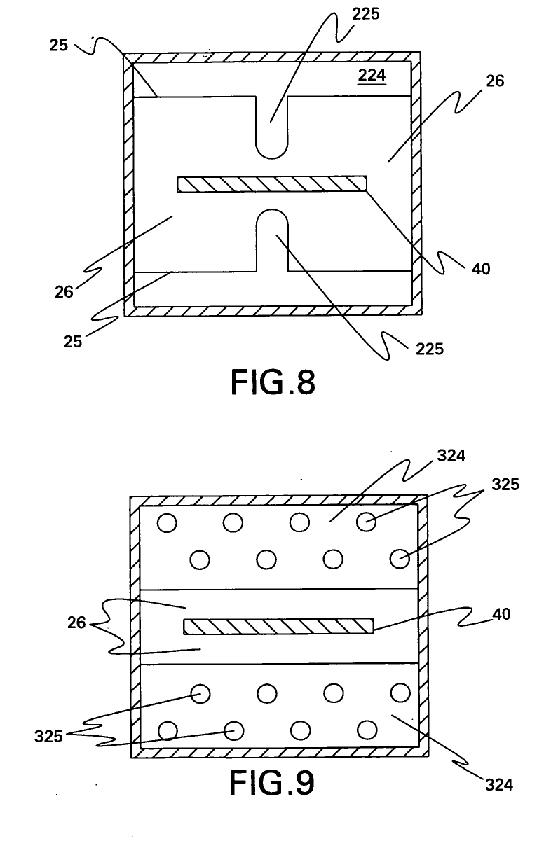

Referring now to FIGS. 6-9, the baffle may have a varying profile. For example, as shown in FIG. 6, the baffle 24 may extend straight across the deposition chamber 18 and have a bottom surface 25 parallel with the web 40. Alternately, and with reference to FIG. 7, a baffle 124 may have a curved surface 125 or an irregularly shaped surface facing the web 40. It may be desirable to include some form of flow obstruction in the opening 26. As shown in FIG. 8, a baffle 224 includes a flow obstruction 225 extending toward the web 40 from the surface 25. It may be desirable to include some migration enhancing features into the baffle. With specific reference to FIG. 9, a baffle 324 is included with a plurality of flow orifices 325 extending there through.

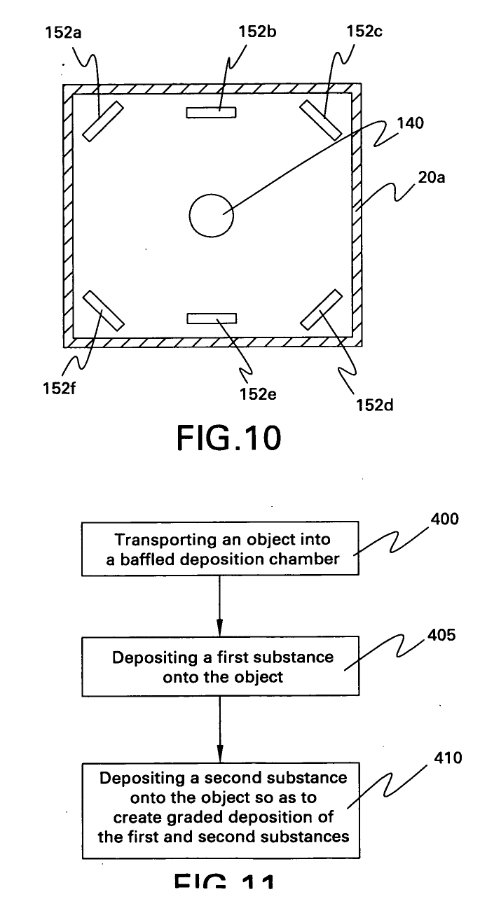

It should further be appreciated that more than one deposition assembly may be positioned in each chamber area. For example, and with specific reference to FIG. 10, a chamber area, such as, for example, the first chamber area 20a, may include a plurality of deposition assemblies 152a-f. Such an arrangement of deposition assemblies 152a-f may be necessary for coating an object 140 having an irregular or curved profile.

Next with reference to FIG. 11 will be described a method for providing a graded-composition coating on an object. At Step 400, an object is transported in to a baffled deposition chamber. The object may be a plurality of discrete articles or a substrate capable of being wound and unwound from and two a pair of spools. The deposition chamber preferably has two or more chamber areas, each separated from the other by a baffle having an opening there through. The opening, which may be adjustable, is configured to allow migration of deposition material from one chamber area to another, thereby enhancing the deposition of a coating having a graded composition.

Next, at Step 405, a first substance or material is deposited on the object. The first substance or material comes from a first or a plurality of first deposition assembly(ies) located in a first chamber area or subchamber. At Step 410, a second substance or material is deposited on the object. The second substance or material comes from a second or a plurality of second deposition assembly(ies) located in a first chamber area or subchamber. The deposition Steps 405 and 410 may occur simultaneously or sequentially. The deposition Steps 405, 410 are performed so as to create a graded deposition of first and second substances on the object.

It should be appreciated that certain mechanical and chemical properties are desirable for substrates to be used in electronic devices such as organic light-emitting devices (OLEDs), organic photovoltaic devices, thin-film transistors (TFTs) and TFT arrays using organic and solution-processible inorganic materials, and other more complicated circuits. Mechanical flexibility of the substrate is of importance for roll-to-roll processing, as described herein. Similar flexibility is also required for various end-use applications, such as, for example, “roll-up” displays. Chemical resistance is also important for substrate compatibility with the various solvents and chemicals in use in organic electronic device fabrication steps. Further discussion of important mechanical and chemical properties for suitable substrates is found in M. Yan, et al., “A Transparent, High Barrier, and High Heat Substrate for Organic Electronices,” IEEE, V. 93, N. 8, August 2005, p. 1468-1477, the entirety of which is incorporated herein by reference.

The compositionally graded ultra-high barrier (UHB) coating described above can effectively stop defects from propagating through the coating thickness. In such a barrier structure, organic materials effectively decouple defects growing in the thickness direction but, instead of having a sharp interface between inorganic and organic materials, there are “transitional” zones where the coating composition varies continuously from inorganic to organic and vice versa. These “transitional” zones bridge inorganic and organic materials, which should result in a single layer structure with improved mechanical stability and stress relaxation relative to that of multilayer barrier structures.

Such a graded diffusion barrier coating also may be used to protect objects that are sensitive to environmental reactive species such as oxygen and water vapor. Such objects include, but are not limited to, organic light emitting diodes (OLEDs), liquid crystal devices (LCDs), photovoltaic cells, electrochromic devices, electrophoretic devices, and the like.

Next will be described various methodologies for ascertaining the effectiveness of the roll to roll process for producing a coating having a graded composition.

Optical emission spectrometry (OES) is a method for identifying specific light frequencies emitted from an article to ascertain the composition of the materials making up the article as well as the relative concentrations of the materials. The energy of plasma induces atoms or ions to lose an electron and reach an “excited” state. As excited atoms and ions relax back to their base states, they give off energy in the form of light. The spectrum of light frequencies emitted from each element is unique and can be used to identify the presence of that element in plasma. This emitted light is separated by wavelength using an optical spectrometer equipped with an Eschelle type grating. The separated light is focused onto a solid-state detector, which identifies each wavelength and its relative intensity. The wavelength can be used to identify gas composition and the intensity on each wavelength corresponds to related gas concentration.

In a first example, the organic and inorganic plasma emissions were studied with Ocean Optics USB2000 Miniature Fiber Optic Spectrometer. During this example, data were collected by spectrometer and analyzed using software provided by Ocean Optics. The organic coating was deposited by a gas mixture of a majority of helium (He) and also silicone oxycarbide precursor at pressure and under RF power. Since most of the gas in plasma is He, it was necessary to differentiate the peaks from He plasma from the peaks from silicone oxycarbide plasma. The emission spectrum was collected for pure He plasma and compared with that for He plus silicone oxycarbide plasma. It was found that the peak that is associated with silicone oxycarbide is at 430.5 nm.

The same procedure was repeated for the inorganic coating plasma. The inorganic coating was deposited by a gas mixture of mainly He, and also NH₃ (ammonia) and SiH₄ (silane) at pressure and under RF power. The emission spectrum for pure He plasma was compared with that for He+NH₃ plus SiH₄ plasma. It was found that the peak associated with ammonia and silane is at 336 nm.

After the peaks for silicone oxycarbide and for ammonia plus silane plasma were identified, the following step was to study whether there was a mixing of gases when those organic and inorganic plasmas were running simultaneously in adjacent subchambers, and how the mixing of gases could be affected by either opening size or pressure difference between the adjacent subchambers.

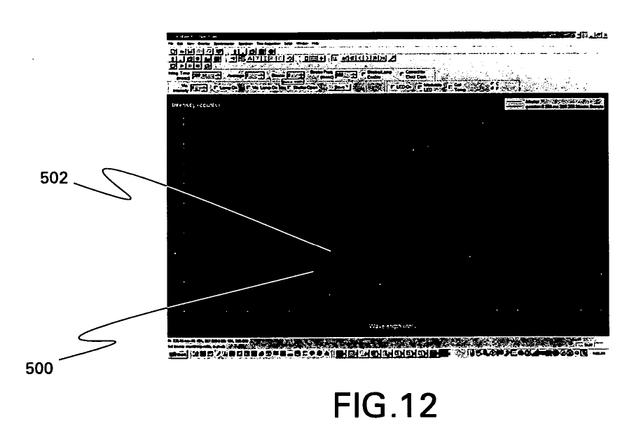

First, the opening, such as opening 26, was left fully open (two inches) with equalized pressure between the adjacent subchambers. OES spectrum was collected from a first location remote from the opening 26 and within the subchamber in which organic process plasma was emitted and compared to the spectrum that would occur from an emission of organic process plasma without inorganic process plasma emission in an adjacent subchamber. Referring specifically to FIG. 12, an organic process plasma emission spectra 500 is shown in juxtaposition to a spectra 502 containing an organic process plasma emission with an inorganic process running in an adjacent subchamber. A peak (336 nm) in the organic process plasma spectra 500 corresponds to ammonia plus silane. This suggests that ammonia and silane have diffused into the subchamber in which the organic process plasma was primarily emitted.

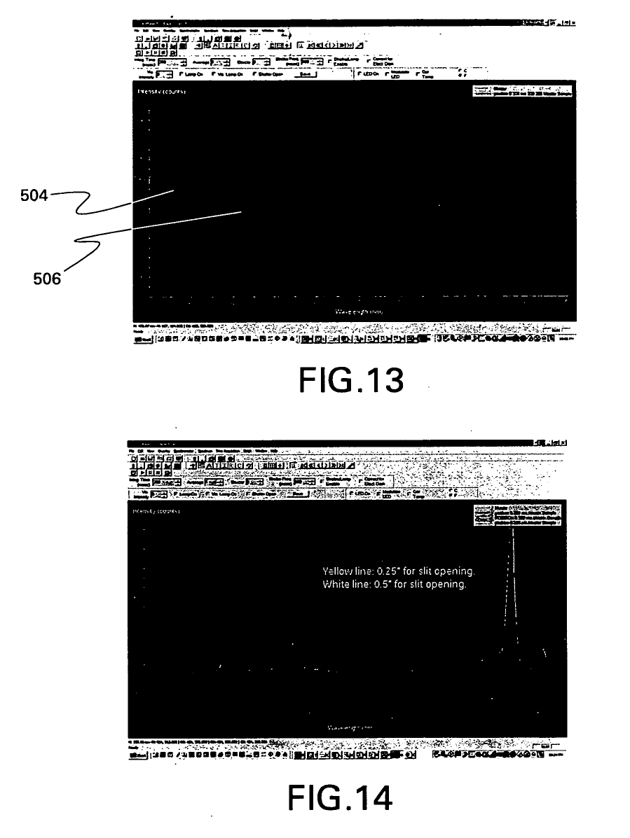

OES spectrum was also collected from second location remote from the opening 26 and within the subchamber in which inorganic process plasma was emitted and compared to the spectrum that would occur from an emission of inorganic process plasma without organic process plasma emission in an adjacent subchamber. FIG. 13 clearly shows an inorganic process plasma emission spectra 504 in juxtaposition to a spectra 506 containing an inorganic process plasma emission with an organic process running in an adjacent subchamber. When the organic process is running in adjacent chamber, there is a peak (430.5 nm) in the inorganic process plasma spectra 506 that corresponds to silicone oxycarbide. This suggests that silicone oxycarbide has diffused into the subchamber in which the inorganic process plasma was primarily emitted.

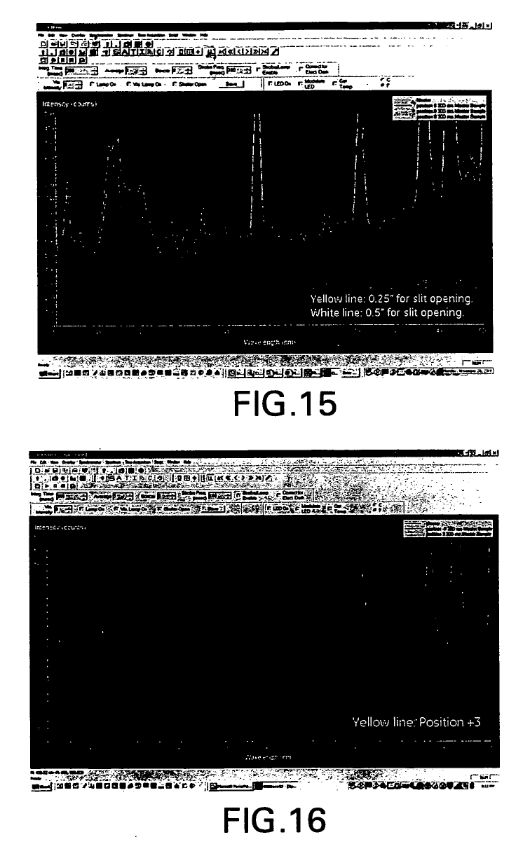

Next, a varied opening 26 was examined with equalized pressure for adjacent subchambers. The size of the opening 26 was changed, set at 0.125 inches, 0.25 inches and 0.5 inches, and OES spectra were collected from within one of the subchambers for both inorganic and organic plasmas. FIG. 14 shows that the intensity of a 336 nm peak (corresponds to ammonia plus silane) in organic process plasma is not sensitive to the size of the opening 26, while FIG. 15 shows the intensity of a 430.5 nm peak (corresponds to silicone oxycarbide) in inorganic process plasma decreases rapidly with a decreasing size of the opening 26. This suggests that the opening 26 size can affect silicone oxycarbide gas diffusing from one subchamber to an adjacent subchamber while the opening 26 size has little effect on the diffusion of ammonia/silane gases.

Additional tests were run to observe the mixing of gases from adjacent subchambers. The opening 26 size was set at 0.25 inches and OES spectra were collected from various positions of within the subchamber into which an inorganic plasma process was running. FIG. 16 shows a comparison of the spectra at various positions within the deposition machine 10. Specifically, FIG. 16 shows that the intensity of 430.5 nm peak (silicone oxycarbide peak) reduces as it moves away from the subchamber into which silicone oxycarbide is initially emitted, thus supporting that the mixing of gas is higher in the mixing area 66 (FIG. 3).

In another example, an optical technique of ellipsometry was used to ascertain properties on a surface of the substrate 40 (FIG. 4). Ellipsometry utilizes a physical phenomenon of reflected light to measure its polarization. Specifically, if linearly polarized light of a known orientation is reflected at oblique incidence from a surface, the reflected light is elliptically polarized. The shape and orientation of the ellipse depend on the angle of incidence, the direction of the polarization of the incident light, and the reflection properties of the surface. One can measure the polarization of the reflected light with a quarter-wave plate followed by an analyzer; the orientations of the quarter-wave plate and the analyzer are varied until no light passes though the analyzer. From these orientations and the direction of polarization of the incident light one can calculate the relative phase change Δ, and the relative amplitude change ψ introduced by reflection from the surface.

An ellipsometer measures the changes in the polarization state of light when it is reflected from a sample. If the sample undergoes a change, for example a thin film on the surface changes its thickness, then its reflection properties will also change. Measuring these changes in the reflection properties allows one to deduce the actual change in the thickness and refractive index of a film.

To study the deposition rate and refractive index of inorganic and organic coating inside the deposition machine 10, a long piece of silicon wafer was taped to a plastic web and ellipsometry was used to study coatings deposited on the wafer. The wafer was long enough to cover the entire deposition area, from the far end of the subchamber into which organic plasma was initially emitted to the opposite far end of subchamber into which inorganic plasma was initially emitted. The web was kept stationary during depositions.

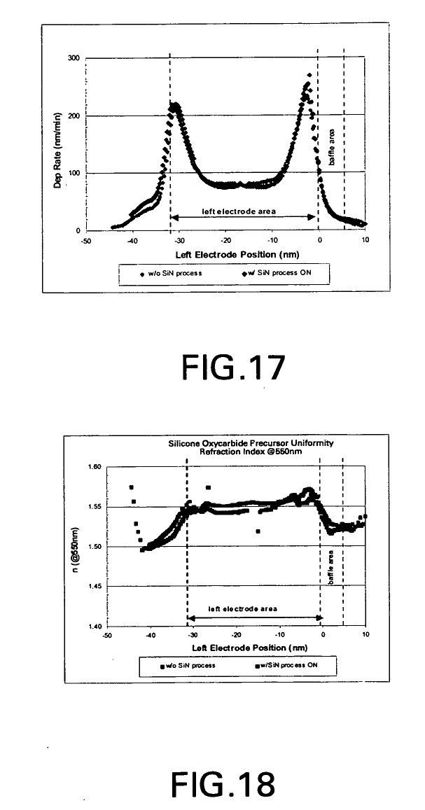

First, an organic coating process was carried out in one subchamber with and without inorganic coating process running in an adjacent subchamber. The organic process was running with a gas mixture of mainly He and also silicone oxycarbide precursor at pressure and under RF power. FIGS. 17 and 18 show, respectively, the deposition rate and the refractive index (at 550 nm) of coatings achieved at various positions in the one subchamber into which the organic plasma was initially emitted, with and without an inorganic coating process running in the adjacent subchamber (with opening 26 fully open). As shown, there is organic deposit in the mixing area 66 even though the deposition rate decreases rapidly as it moves away from the location where the organic emission initially occurs. The introduction of the inorganic plasma process in the adjacent subchamber does not significantly affect the organic plasma process.

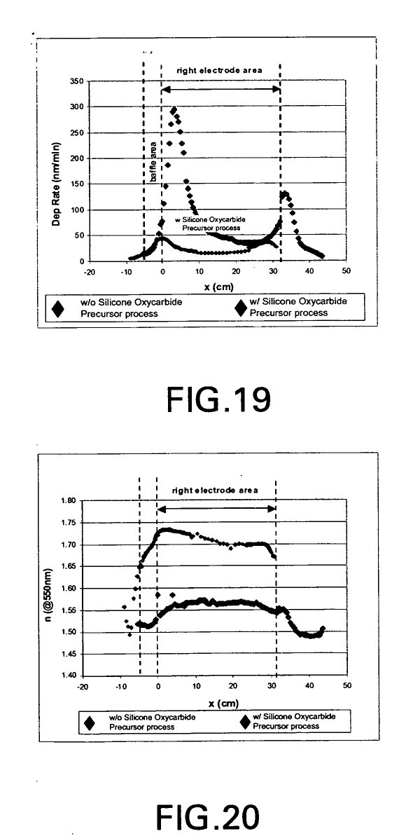

Additionally, an inorganic coating process was carried out in one subchamber both with and without an organic coating process running in an adjacent subchamber. The inorganic coating was deposited by a gas mixture of mainly He, along with NH₃ (ammonia) and SiH₄ (silane) at pressure and under RF power. FIGS. 19 and 20 show, respectively, the deposition rate and the refractive index (at 550 nm) of coatings achieved at various positions in the one subchamber into which the inorganic plasma was initially emitted, with and without an organic coating process running in the adjacent subchamber (with opening 26 fully open). As shown, the introduction of the organic plasma process in the adjacent subchamber adversely affected the inorganic coating process, resulted in a coating having a high deposition rate and lowered refractive index.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed as new and desired to be protected by Letters Patent of the United States is:

1. A continuous deposition machine, comprising:
a deposition chamber including at least two subchambers separated by a baffle having an opening; and
a transportation device extending through said deposition chamber.

2. The continuous deposition machine of claim 1, wherein said at least two subchambers comprise a first subchamber and a second subchamber, further comprising:
a first deposition assembly adapted to deposit a first material and being positioned in said first subchamber and a second deposition assembly adapted to deposit a second material and being positioned in said second subchamber.

3. The continuous deposition machine of claim 2, further comprising a mix area, said mix area location being determined by differential pressures between said first and second subchambers.

4. The continuous deposition machine of claim 3, wherein said mix area is located adjacent to said baffle and wherein said mix area comprises an area of said first and second subchambers where material from said first deposition assembly is equally as likely to migrate into said second subchamber as it is to remain in said first subchamber and where material from said second deposition assembly is equally as likely to migrate into said first subchamber as it is to remain in said second subchamber.

5. The continuous deposition machine of claim 2, further comprising a first outlet or outlets positioned in said first subchamber and a second outlet or outlets positioned in said second subchamber, wherein said first and second outlets are configured to allow excess material from said first and second deposition assemblies to exit said deposition chamber.

6. The continuous deposition machine of claim 2, wherein said opening is adjustable for controlling a migration rate of said first material through said opening into said second subchamber and a migration rate of said second material through said opening into said first subchamber.

7. The continuous deposition machine of claim 2, wherein said first and second deposition assemblies comprise chemical vapor deposition assemblies.

8. The continuous deposition machine of claim 7, wherein said chemical vapor deposition assemblies comprise plasma enhanced chemical vapor deposition assemblies.

9. The continuous deposition machine of claim 2, wherein said first and second deposition assemblies comprise evaporation assemblies.

10. The continuous deposition machine of claim 1, wherein said transportation device comprises a pair of spools and a web, wherein a first of said pair of spools is adapted to unwind the web and a second of said pair of spools is adapted to wind the web.

11. The continuous deposition machine of claim 10, wherein said web comprises a substrate for deposition.

12. The continuous deposition machine of claim 11, wherein said web comprises an object for deposition.

13. The continuous deposition machine of claim 1, wherein the deposition chamber is configured to allow selective addition or subtraction of subchambers.

14. A continuous deposition machine for depositing a graded coating on a substrate, comprising:
a deposition chamber including a first chamber area separated from a second chamber area by a baffle having an opening;
an unwinding chamber including an unwinding spool and a winding chamber including a winding spool;
a substrate wound on said unwinding spool and extending through said deposition chamber to said winding spool; and
a first chemical vapor deposition assembly located in said first chamber area and a second chemical vapor deposition assembly located in said second chamber area.

15. The continuous deposition machine of claim 14, wherein said deposition chamber is under vacuum.

16. A system for forming a graded coating on an object, comprising:
a continuous deposition machine, comprising:
a deposition chamber including at least two subchambers separated by a baffle having an opening; and
a transportation device adapted for transporting an object through said deposition chamber; and
a pump for enacting a vacuum in said deposition chamber.

17. The system of claim 16, wherein each of said at least two subchambers comprises:
at least one deposition assembly, each said at least one deposition assembly being adapted for depositing a material on the object; and
an outlet configured to allow excess material from each said at least one deposition assembly to exit said deposition chamber.

18. The system of claim 17, wherein said opening is adjustable for controlling a migration rate of said material through said opening.

19. The system of claim 17, further comprising a mix area located adjacent to said baffle, wherein said mix area comprises a portion of each of said at least two subchambers where material being deposited is equally as likely to migrate through the opening as it is to remain in the subchamber in which it was released.

20. The system of claim 16, wherein each said at least one deposition assembly is adapted for one from the consisting of chemical-vapor deposition, plasma-enhanced chemical-vapor deposition, radio-frequency plasma-enhanced chemical-vapor deposition, expanding thermal-plasma chemical-vapor deposition, sputtering, reactive sputtering, electron-cyclotron-resonance plasma-enhanced chemical-vapor deposition, inductively coupled plasma-enhanced chemical-vapor deposition, and evaporation.

21. The system of claim 16, wherein said transportation device comprises a first spool, a web, and a second spool, wherein said first spool is adapted to unwind the web and said second spool is adapted to wind the web.

22. The system of claim 21, wherein the object comprises said web.

23. The system of claim 22, wherein said web comprises a substrate comprising at least one material from the group consisting of polymer, glass, metal, paper, and fabric.

24. A system for forming an electronic device, comprising:
a deposition machine, comprising:
a deposition chamber having a first chamber area separated from a second chamber area by a baffle having an opening;
a first deposition assembly in said first chamber area and a second deposition assembly in said second chamber area, said first and second deposition assemblies being adapted for depositing materials on a substrate to form a coating on said substrate; and
a first outlet configured to allow excess material to exit from said first chamber area and a second outlet configured to allow excess material to exit from said second chamber area;
a transportation device adapted for continuously transporting said substrate through said deposition chamber;
a pump for enacting a vacuum in said deposition chamber.

25. The system of claim 24, wherein said coating comprises a diffusion-barrier coating having a graded composition.

26. The system of claim 24, wherein said substrate comprises at least one material from the group consisting of polymer, glass, metal, paper, and fabric.

27. The system of claim 24, wherein the electronic device comprises one from the group consisting of an electroluminescent device, a photovoltaic device, a flexible light source based on organic light-emitting materials, a liquid crystal display, a flexible integrated circuit, an electrochromic device, an electrophoretic device, and a component of a medical diagnostic device.

28. The system of claim 24, further comprising a vacuum for providing a vacuum to said deposition chamber.

29. The system of claim 24, wherein said opening is adjustable for controlling a migration rate of said material through said opening.

30. The system of claim 24, wherein said baffle includes a flow obstruction in said opening.

31. The system of claim 24, wherein said baffle includes a plurality of orifices.

32. The system of claim 24, comprising a plurality of deposition assemblies in each of said first and second chamber areas.

33. A method for forming a graded coating having a varying composition on an object, comprising:
transporting an object through a deposition chamber including a first chamber area separated by a second chamber area by a baffle having an opening; and
depositing a first substance and a second substance on a surface of the object to create a graded coating having a varying composition in a direction orthogonal to the surface of the object.

34. The method of claim 33, wherein said transporting comprises continuously moving the object through the deposition chamber.

35. The method of claim 34, wherein the object comprises a substrate and said transporting comprises unwinding the substrate from a first spool prior to transporting the substrate through the deposition chamber and winding the substrate onto a second spool upon exit from the deposition chamber.

36. The method of claim 33, wherein said depositing comprises one or more from the group consisting of chemical-vapor deposition, plasma-enhanced chemical-vapor deposition, radio-frequency plasma-enhanced chemical-vapor deposition, expanding thermal-plasma chemical-vapor deposition, sputtering, reactive sputtering, electron-cyclotron-resonance plasma-enhanced chemical-vapor deposition, inductively coupled plasma-enhanced chemical-vapor deposition, and evaporation.

37. The method of claim 33, wherein said depositing comprises depositing the first substance from at least one deposition assembly and depositing the second substance from at least one deposition assembly.

38. The method of claim 37, wherein the deposition chamber comprises a mix area located adjacent to the baffle and comprising a portion of the first and second subchambers where material from the first deposition assembly is equally as likely to migrate into the second subchamber as it is to remain in said first subchamber and where material being deposited is equally as likely to migrate through the opening as it is to remain in the subchamber in which it was released, said depositing comprising:
depositing the first substance onto the object outside of the mix area to provide a first coating portion having a composition primarily of the first substance;
depositing the first and second substances onto the object within the mix area to provide a second coating portion having a composition of the first and the second substances; and
depositing the second substance onto the object outside of the mix area to provide a third coating portion having a composition primarily of the second substance.

39. The method of claim 33, further comprising providing a vacuum within the deposition chamber.
